(19) United States
(12) Patent Application Publication
(10) Pub. No.: US 2008/0121911 A1
(43) Pub. Date: May 29, 2008

(54) OPTICAL PREFORMS FOR SOLID STATE LIGHT EMITTING DICE, AND METHODS AND SYSTEMS FOR FABRICATING AND ASSEMBLING SAME

(75) Inventors: Peter S. Andrews, Durham, NC (US); Ronan P. Le Toquin, Durham, NC (US)

Correspondence Address: MYERS BIGEL SIBLEY & SAJOVEC, P.A., P.O. BOX 37428, RALEIGH, NC, 27627, US

(73) Assignee: Cree, Inc.

(21) Appl. No.: 11/563,840

(22) Filed: Nov. 28, 2006

(51) Int. Cl. H01L 33/00

(52) U.S. Cl. 257/98; 438/29; 257/E33.001

(57) ABSTRACT

A preform is attached to a solid state light emitting die. One or more optical elements, such as a photoluminescent element, a refracting element, a filtering element, a scattering element, a diffusing element or a reflecting element, is included in and/or on the preform. For example, the preform may be a glass preform with phosphor particles suspended therein. The preform may be fabricated using microelectronic manufacturing techniques, and may be placed on the solid state light emitting die using pick and place techniques.

### FIELD OF THE INVENTION

This invention relates to solid state light emitting devices and fabrication methods therefor, and more particularly to packaging for solid state light emitting dice.

### BACKGROUND OF THE INVENTION

Solid state light emitting devices, such as inorganic or organic Light Emitting Diodes (LEDs), are widely used for many applications. As is well known to those having skill in the art, a solid state light emitting device includes a solid state light emitting die or chip that is configured to emit coherent and/or incoherent light upon energization thereof. An inorganic LED may include semiconductor layers that form P-N junctions. An organic LED may include one or more organic light emission layers. Typically, a solid state light emitting device generates light through the recombination of electronic carriers, i.e., electrons and holes, in a light emitting layer or region.

It is also known that a solid state light emitting die may be packaged to provide external electrical connections, heat sinking, lenses, waveguides and/or other optical functionality, environmental protection and/or other desired functionality. Packaging may be provided, at least in part, by mounting the solid state light emitting die on a submount and/or at least partially surrounding the solid state light emitting die with a dome-shaped shell.

It is often desirable to incorporate phosphor into a solid state light emitting device, to enhance the emitted radiation in a particular frequency band and/or to convert at least some of the radiation to another frequency band. As used herein, the term “phosphor” is used generically for any photoluminescent material. Phosphors may be included in a solid state light emitting device using many techniques. For example, phosphor may be coated inside and/or outside the dome-shaped shell and/or included within the shell itself. In other techniques, phosphor may be coated on the solid state light emitting die itself. In still other techniques, a drop of material, such as epoxy, silicone encapsulant, etc., that contains phosphor therein, may be placed on the die and cured to form a shell over the die. This technique may be referred to as a “glob top”.

Unfortunately, the packaging for a solid state light emitting die may be costly and, in some cases, more costly than the solid state light emitting die itself. Moreover, the assembly process also may be costly, time consuming and/or subject to failures. Finally, the packaging may undesirably decrease the extraction efficiency of light from the solid state light emitting die and/or degrade optical characteristics of the emitted light.

### SUMMARY OF THE INVENTION

Solid state light emitting devices according to some embodiments of the present invention comprise a solid state light emitting die that is configured to emit light upon energization thereof, and a preform that is configured to allow at least some light that is emitted from the solid state light emitting die to pass therethrough. A layer attaches and optically couples the preform and the solid state light emitting die to one another. An optical element is provided in and/or on the preform that is configured to modify at least some of the light that is emitted from the solid state light emitting die. By using a preform that is attached and optically coupled to the solid state light emitting die itself, high efficiency optical processing of the light emitted from the solid state light emitted die may be provided. Moreover, the preform may be fabricated using conventional microelectronic manufacturing techniques, and may be placed on the solid state light emitting die using conventional “pick and place” techniques, so that manufacturing cost, time and/or yield may be increased. In some embodiments, the layer adhesively attaches the preform and the solid state light emitting die to one another.

Many types of preforms may be provided according to various embodiments of the present invention. Generally, the preform may comprise a flexible and/or inflexible material. For example, a flexible preform may comprise a silicone-based material, such as Room Temperature Vulcanizing (RTV) silicone rubber, silicone gels, silicone rubbers, silicone-epoxy hybrids, etc. An inflexible preform may comprise glass.

The preform may be provided in various sizes and shapes. For example, in some embodiments, the preform is of the same shape and size as a surface of the light emitting die. In other embodiments, the preform extends beyond the surface of the light emitting die. In other embodiments, the light emitting die includes an external contact pad and the preform may be shaped so as to expose the external contact pad. The preform may be of uniform thickness or of variable thickness. Moreover, the preform may have an extended sidewall that is configured to extend along a sidewall of the solid state light emitting die.

Moreover, various types of optical elements may be provided in and/or on the preform, that is/are configured to modify at least some of the light that is emitted from the solid state light emitting die by changing the amplitude, frequency and/or direction of at least some of the light that is emitted from the solid state light emitting die. For example, the optical element may comprise a photoluminescent element such as phosphor, an optical refracting element such as a lens, an optical filtering element such as a color filter, an optical scattering element such as light scattering particles, and optical diffusing element such as a textured surface, an optical reflecting element such as a mirrored surface and/or another preform, in and/or on the preform. In still other embodiments, an electrical element, such as a wiring or bonding element, may also be provided in and/or on the preform.

In some embodiments, the preform may comprise a suspension of phosphor particles in glass. In some embodiments, between about 30 and about 95 weight percent phosphor particles may be provided. In other embodiments, the phosphor particles may be between about 0.5 μm and about 30 μm in diameter. In still other embodiments, about 0.001 to about 1.0 weight percent optical scattering particles may be provided. In yet other embodiments, a textured surface may be provided on the preform, to provide a diffusing element.

In still other embodiments, the solid state light emitting device may further include a second preform that is configured to allow at least some light that is emitted from the solid state light emitting die to pass therethrough, a second layer that attaches and optically couples the second preform and the first preform to one another, remote from the solid state light emitting die, and a second optical element in and/or on the second preform that is configured to further modify at least some of the light that is emitted from the solid state light emitting die. In some embodiments, the second layer adhesively attaches and optically couples the second preform and the first preform to one another. Accordingly, a series of preforms may be provided on the solid state light emitting die that can perform similar and/or different optical functions.

In still other embodiments of the present invention, a submount also may be provided that is connected to the solid state light emitting die that includes the preform thereon. The submount may be further packaged to provide external electrical connections, heat sinking, environmental protection and/or other conventional functions for the solid state light emitting device. It will also be understood that any and all of the above-described embodiments of preforms and optical elements may be used in various combinations and subcombinations.

Embodiments of the invention were described above in connection with an assembled solid state light emitting device that includes a solid state light emitting die, a preform, a layer and an optical element. However, other embodiments of the present invention can provide an optical processing device for a solid state light emitting die that is embodied as a preform that is sized and shaped to adhesively attach to the solid state light emitting die. The preform is configured to allow at least some light that is emitted from the solid state light emitting die to pass therethrough. An optical element is provided in and/or on the preform that is configured to modify at least some of the light that is emitted from the solid state light emitting die. Various embodiments of preforms and/or optical elements may be provided as was described above.

Still other embodiments of the present invention provide an optical processing device for a solid state light emitting die that comprises a glass preform that is sized and shaped to attach to the solid state light emitting die, wherein the glass preform includes phosphor particles suspended therein. Various embodiments of glass preforms, phosphor particles, light scattering particles and/or texturing may be provided, as described above. Moreover, in some embodiments, the phosphor may comprise Ce:YAG phosphor and/or other phosphors such as Eu2+ doped BOSE, Ce3+ doped nitrides, etc.

Moreover, optical processing devices that include a preform and an optical element may be fabricated on a large scale by fabricating precursors that include large numbers of preforms on a flexible and/or inflexible substrate and then singulating the preforms. The preforms may be singulated on a temporary substrate, such as conventional “blue tape”. A respective preform may then be placed on a respective solid state light emitting die using well known “pick and place” equipment and techniques.

Accordingly, some embodiments of the present invention can provide a precursor that includes a substrate and a plurality of preforms on the substrate, a respective preform including optical elements thereon and/or therein. Systems and/or methods for attaching a preform and a solid state light emitting die to one another also may be provided in other embodiments. In some embodiments, the precursor may comprise singulated preforms. In other embodiments, the singulated preforms may also comprise flexible material, and the substrate may also comprise a singulated substrate. In other embodiments, the singulated preforms may comprise glass and the optical element may comprise phosphor particles suspended in the singulated glass preforms.

Methods of fabricating a solid state light emitting device may also be provided, wherein a preform and a solid state light emitting die are attached to one another and wherein the preform includes an optical element therein and/or thereon. In some embodiments, the attaching is performed by picking the preform from a substrate and placing the preform that was picked onto the solid state light emitting die. Placing may be preceded by coating adhesive on the preform and/or the solid state light emitting die. Picking may be preceded by a singulating the preform.

In still other embodiments, the preform itself may be fabricated by suspending phosphor particles in glass. The suspending may be performed, according to some embodiments, by mixing glass frit and phosphor particles, and heating to melt the glass frit and form a glass preform including the phosphor particles suspended therein. In other embodiments, suspending may be performed by mixing phosphor particles into molten glass, and then allowing the molten glass to cool.

### BRIEF DESCRIPTION OF THE DRAWINGS

FIGS. 1A-1F are cross-sectional views of various configurations of conventional light emitting diodes.

FIG. 1G is a cross-sectional view of a conventional packaged light emitting diode.

FIGS. 2A-2F are cross-sectional views of solid state light emitting devices according to various embodiments of the present invention during intermediate fabrication thereof.

FIGS. 3A-3F are cross-sectional views of solid state light emitting devices after preform attachment, according to various embodiments of the present invention.

FIG. 3G is a cross-sectional view of a packaged device of FIG. 3F, according to various embodiments of the present invention.

FIGS. 3H-3M are cross-sectional views of solid state light emitting devices after preform attachment, according to various embodiments of the present invention.

FIG. 3N is a cross-sectional view of a packaged device of FIG. 3M, according to various embodiments of the present invention.

FIG. 4 is a flowchart of operations that may be performed to fabricate solid state light emitting devices according to various embodiments of the present invention.

FIGS. 5A-5F are cross-sectional views of solid state light emitting devices according to other embodiments of the present invention.

FIGS. 6A-6F are cross-sectional views of solid state light emitting devices according to yet other embodiments of the present invention.

FIGS. 7A-7F are cross-sectional views of solid state light emitting devices according to still other embodiments of the present invention.

FIGS. 8A-8F are cross-sectional views of solid state light emitting devices according to further embodiments of the present invention.

FIGS. 9A-9F are cross-sectional views of solid state light emitting devices according to still further embodiments of the present invention.

FIG. 10 is a flowchart of operations that may be performed to fabricate flexible preforms according to various embodiments of the present invention.

FIG. 11 schematically illustrates methods and systems for fabricating flexible preforms of FIG. 10.

FIG. 12 is a flowchart of operations for fabricating rigid preforms according to some embodiments of the present invention.

FIGS. 13A-13C schematically illustrate various systems and methods for fabricating rigid preforms according to some embodiments of the present invention.

FIG. 14 is a cross-sectional view of a large area preform that is configured to attach to multiple solid state light emitting dice according to various embodiments of the present invention.

FIG. 15 is a schematic illustration of a display unit having a backlight including a light emitting device according to some embodiments of the invention.

FIG. 16 is a schematic illustration of a solid state luminaire including a light emitting device according to some embodiments of the invention.

### DETAILED DESCRIPTION

The invention will be described more fully hereinafter with reference to the accompanying drawings, in which example embodiments of the invention are shown. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of layers and regions may be exaggerated for clarity. Moreover, each embodiment described and illustrated herein includes its complementary conductivity type embodiment as well. Like numbers refer to like elements throughout.

It will be understood that when an element or layer is referred to as being “connected to,” “coupled to” or “responsive to” (and/or variants thereof) another element, it can be directly connected, coupled or responsive to the other element or intervening elements may be present. In contrast, when an element is referred to as being “directly connected to,“ ”directly coupled to” or “directly responsive to” (and/or variants thereof) another element, there are no intervening elements present. Like numbers refer to like elements throughout. As used herein, the term “and/or” includes any and all combinations of one or more of the associated listed items and may be abbreviated as “/”.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising” (and/or variants thereof), when used in this specification, specify the presence of stated features, integers, steps, operations, elements, and/or components, but do not preclude the presence or addition of one or more other features, integers, steps, operations, elements, components, and/or groups thereof, In contrast, the term “consisting of” (and/or variants thereof) when used in this specification, specifies the stated number of features, integers, steps, operations, elements, and/or components, and precludes additional features, integers, steps, operations, elements, and/or components.

The present invention is described below with reference to block diagrams and/or flowchart illustrations of methods and/or apparatus (systems) according to embodiments of the invention. It is understood that a block of the block diagrams and/or flowchart illustrations, and combinations of blocks in the block diagrams and/or flowchart illustrations, can embody apparatus/systems (structure), means (function) and/or steps (methods) for implementing the functions/acts specified in the block diagrams and/or flowchart block or blocks.

It should also be noted that in some alternate implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Example embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, may be expected. Thus, the disclosed example embodiments of the invention should not be construed as limited to the particular shapes of regions illustrated herein unless expressly so defined herein, but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention, unless expressly so defined herein.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and the present application, and will not be interpreted in an idealized or overly formal sense unless expressly so defined herein.

As used herein, the term “preform” means a flexible or inflexible solid structure that is fabricated separate from a solid state light emitting die, and is then attached to the solid state light emitting die. Moreover, “adhesively attaching” means bonding two elements to one another. The bonding may be direct via a single adhesive layer or via one or more intermediate adhesive and/or other layers/structures, to form a unitary structure of the solid state light emitting die and the preform that is adhesively attached thereto, such that this unitary structure may be placed on a submount or other packaging element. Finally, the term “transparent” means that optical radiation from the solid state light emitting device can pass through the material without being totally absorbed or totally reflected.

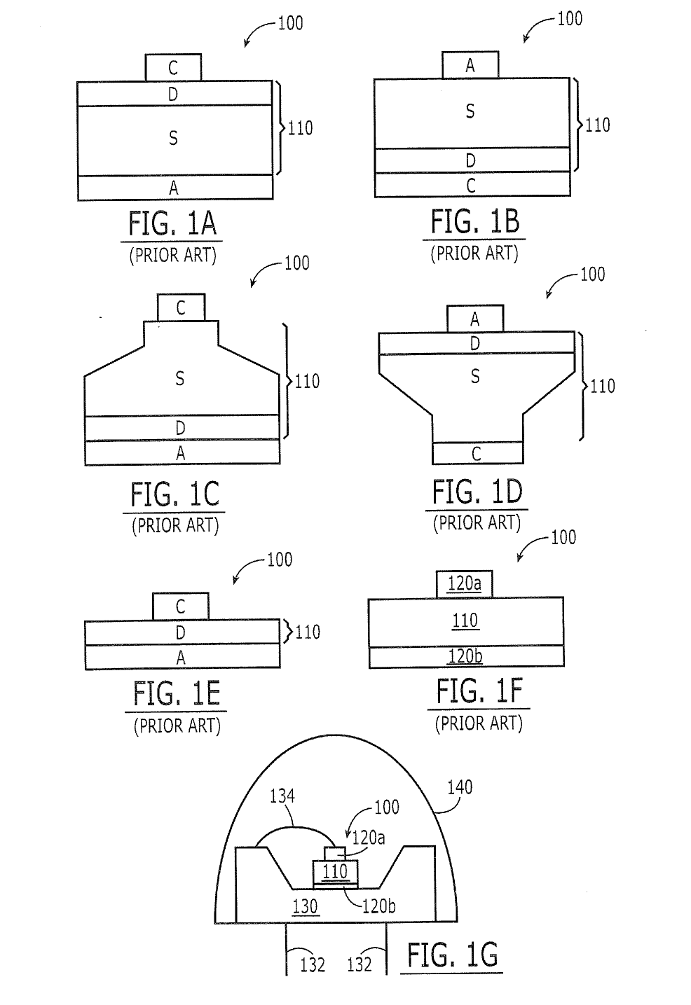

FIGS. 1A-1E are cross-sectional views of various configurations of conventional light emitting diodes (LEDs) that may be used with preforms and optical elements, according to various embodiments of the present invention. As shown in FIGS. 1A-1E, a solid state light emitting device 100 includes a solid state light emitting die 110 that may comprise a diode region D and a substrate S. The diode region D is configured to emit light upon energization thereof, by applying a voltage between an anode contact A and a cathode contact C. The diode region D may comprise organic and/or inorganic materials. In inorganic devices, the substrate S may comprise silicon carbide, sapphire and/or any other single element and/or compound semiconductor material, and the diode region D may comprise silicon carbide, gallium nitride, gallium arsenide, zinc oxide and/or any other single element or compound semiconductor material, which may be the same as or different from the substrate S. The substrate S may be between about 100 μm and about 250 μm thick, although thinner and thicker substrates may be used or the substrate may not be used at all. The cathode C and anode A contacts may be formed of metal and/or other conductors, and may be at least partially transparent and/or reflective. The design and fabrication of organic and inorganic LEDs are well known to those having skill in the art and need not be described in detail herein. LEDs such as depicted in FIGS. 1A-1E may be marketed by Cree, Inc., the assignee of the present application, for example under the designators XThin®, MegaBright®, EZBright™, UltraThin™, RazerThin®, XBright®, XLamp® and/or other designators, and by others.

In FIG. 1A, light emission may take place directly from the diode region D. In contrast, in embodiments of FIG. 1B, emission may take place from diode region D through the substrate S. In FIGS. 1C and 1D, the substrate S may be shaped to enhance emission from sidewalls of the substrate S and/or to provide other desirable effects. Finally, in FIG. 1E, the substrate itself may be thinned considerably or eliminated entirely, so that only a diode region D is present. Moreover, in all of the above embodiments, the anode A and cathode C contacts may be of various configurations and may be provided on opposite sides of the solid state light emitting die 110, as illustrated, or on the same side of the solid state light emitting die 110. Multiple contacts of a given type also may be provided.

FIG. 1F provides a generalization of FIGS. 1A-1E, by providing a solid state light emitting device 100 that comprises a solid state light emitting die 110 that includes a diode region D of FIGS. 1A-1E and also may include substrates of FIGS. 1A-1E, and that is configured to emit light upon energization thereof via one or more contacts 120a, 120b, which may include the anode A and cathode C of FIGS. 1A-1E.

FIG. 1G illustrates a solid state light emitting device 100 of FIG. 1F that is packaged by mounting the device 100 on the submount 130 that provides external electrical connections 132 using one or more wire bonds 134 and also provides a protective dome or cover 140. Many other packaging techniques may be employed to package a solid state light emitting die, as is well known to those having skill in the art, and need not be described further herein. For example, packaging techniques are described in U.S. Pat. No. 6,791,119, issued Sep. 14, 2004 to Slater, Jr. et al., entitled Light Emitting Diodes Including Modifications for Light Extraction; U.S. Pat. No. 6,888,167, issued May 3, 2005 to Slater, Jr. et al., entitled Flip-Chip Bonding of Light Emitting Devices and Light Emitting Devices Suitable for Flip-Chip Bonding; U.S. Pat. No. 6,740,906, issued May 24, 2004 to Slater, Jr. et al., entitled Light Emitting Diodes Including Modifications for Submount Bonding; U.S. Pat. No. 6,853,010, issued Feb. 8, 2005 to Slater, Jr. et al., entitled Phosphor-Coated Light Emitting Diodes Including Tapered Sidewalls, and Fabrication Methods Therefor; U.S. Pat. No. 6,885,033, issued Apr. 26, 2005 to Andrews, entitled Light Emitting Devices for Light Conversion and Methods and Semiconductor Chips for Fabricating the Same; and U.S. Pat. No. 7,029,935, issued Apr. 18, 2006 to Negley et al., entitled Transmissive Optical Elements Including Transparent Plastic Shell Having a Phosphor Dispersed Therein, and Methods of Fabricating Same; U.S. Patent Application Publications Nos. 2005/0051789, published Mar. 10, 2005 to Negley et al., Solid Metal Block Mounting Substrates for Semiconductor Light Emitting Devices, and Oxidizing Methods for Fabricating Same; 2005/0212405, published Sep. 29, 2005 to Negley, Semiconductor Light Emitting Devices Including Flexible Film Having Therein an Optical Element, and Methods of Assembling Same; 2006/0018122, published Jan. 26, 2006 to Negley, Reflective Optical Elements for Semiconductor Light Emitting Devices; 2006/0061259, published Mar. 23, 2006 to Negley, Semiconductor Light Emitting Devices Including Patternable Films Comprising Transparent Silicone and Phosphor, and Methods of Manufacturing Same; 2006/0097385, published May 11, 2006 to Negley, Solid Metal Block Semiconductor Light Emitting Device Mounting Substrates and Packages Including Cavities and Heat Sinks, and Methods of Packaging Same; 2006/0124953 published Jun. 15, 2006 to Negley et al., Semiconductor Light Emitting Device Mounting Substrates and Packages Including Cavities and Cover Plates, and Methods of Packaging Same; and 2006/0139945, published Jun. 29, 2006 to Negley et al., Light Emitting Diode Arrays for Direct Backlighting of Liquid Crystal Displays; and U.S. application Ser. No. 11/408,767, filed Apr. 21, 2006 for Villard, Multiple Thermal Path Packaging For Solid State Light Emitting Apparatus And Associated Assembling Methods, all assigned to the assignee of the present invention, the disclosures of which are hereby incorporated herein by reference in their entirety as if set forth fully herein.

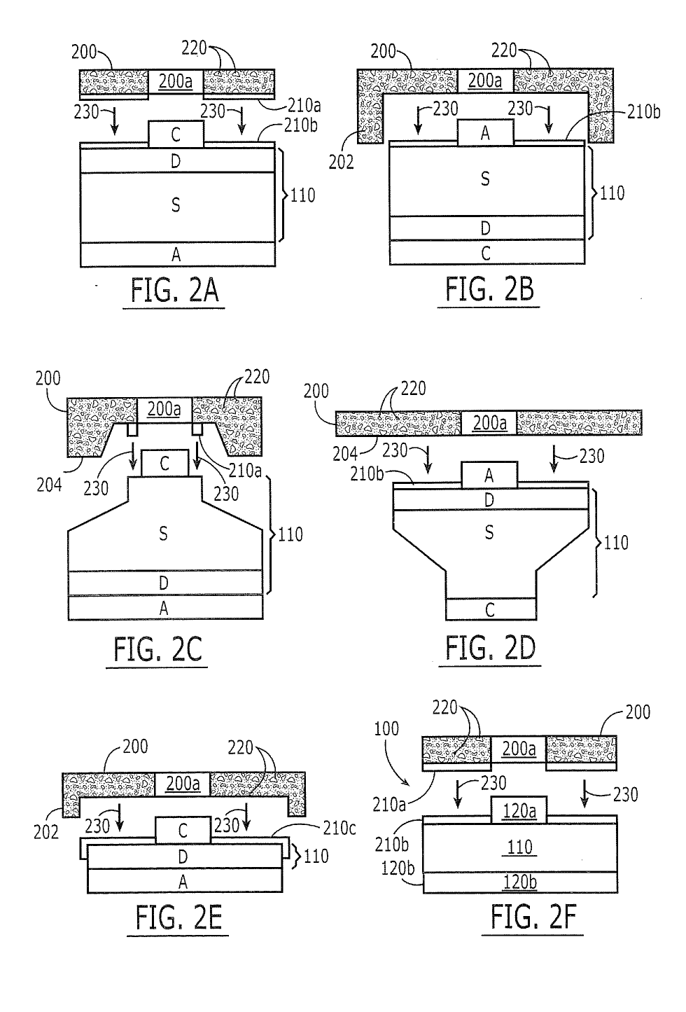

FIGS. 2A-2F are cross-sectional views of solid state light emitting devices according to various embodiments of the present invention during intermediate fabrication thereof. The respective solid state light emitting devices of FIGS. 2A-2F employ the respective solid state light emitting dice of FIGS. 1A-1F.

As shown in FIG. 2A, a preform 200 is configured to allow at least some light that is emitted from the solid state light emitting die 110 to pass therethrough. Stated differently, the preform is transparent to radiation from the solid state light emitting die 110. A layer 210a, 210b, such as an adhesive layer, also may be provided on the preform 200 and/or on the die 110 that attaches, such as adhesively attaches, the preform 200 and the solid state light emitting die 110 to one another as shown by arrows 230 and also optically couples the preform 200 and the solid state light emitting die 110 to one another. An optical element is provided in and/or on the preform 200. The optical element is configured to modify at least some of the light that is emitted from the solid state light emitting die 110. As shown in FIGS. 2A-2F, the optical element may comprise phosphor particles 220 that are suspended in the preform 200. However, other optical elements may be provided according to other embodiments of the present invention, as will be described in detail below. It will also be understood that, in some embodiments, the layer 210a, 210b may be provided only on the preform 200 or only on the die 110.

As also shown in FIG. 2A, the preform 200 may comprise a flexible and/or inflexible material. An example of a flexible material is a silicone-based Room Temperature Vulcanizing (RTV) rubber material and/or a silicone-based polymer material that is widely available, for example from Dow Corning, Shin-Etsu, NuSil, GE and others. An example of an inflexible material is glass. The layer 210a, 210b may be transparent epoxy, such as a thermoset silicone gel or rubber, that is available from Dow Corning, Shin-Etsu, NuSil, GE and others, and/or any other transparent epoxy. In some embodiments, the preform may be the approximate size of a face of an LED die, for example about 1000 μm×1000 μm, and may have a thickness of between about 15 μm and about 75 μm. However, other dimensions may be provided in other embodiments.

As also shown in FIG. 2A, the solid state light emitting die may include an external contact pad, such as cathode C, and the preform 200 may include a notch, hole and/or other void 200a that is configured so as to expose the external contact pad C. In embodiments of FIG. 2A, the preform 200 is planar and may be of uniform thickness. Moreover, the preform 200 of FIG. 2A may be of same size and shape as a surface of the solid state light emitting die 110, except for a void, notch or other surface feature 200a that may be provided to expose an external contact C. It may be desirable to provide one or most features in the preform to facilitate alignment of the preform 200 to the die 110.

FIG. 2B illustrates other embodiments of the present invention, wherein the preform 200 is nonplanar and may include, for example, a sidewall 202 that is configured to extend along a sidewall of the solid state light emitting die 110. Radiation that is emitted from the sidewall of the solid state light emitting die may thereby pass through the preform 200, as well as radiation that is emitted from the major surface to which the preform is attached. The sidewall 202 may extend partway or fully along the sidewall of the die. Moreover, in some embodiments, the preform may extend all the way around the die, including on the sidewalls and the opposing faces of the die. The layer 210b may be located on the die as shown in FIG. 2B, and may also be provided on the preform 200 including on the sidewall 202 of the preform 200 and/or on the sidewall of the die 110.

FIG. 2C illustrates other embodiments of the present invention, wherein the preform extends beyond a surface of the die 110. Accordingly, as shown in FIG. 2C, the preform 200 overhangs a surface of the solid state light emitting die 110. By providing an overhang, radiation from a sidewall of the device may pass through the preform 200. As also shown in FIG. 2C, the overhang 204 may be thicker than the remaining portion of the preform 200. Moreover, the overhang 204 may extend a large distance beyond the die and may extend to a sidewall of a cavity in which the die 110 is mounted, so that substantially all light that is emitted from the cavity passes through the preform.

FIG. 2D illustrates other embodiments, wherein a uniform thickness preform 200 may include an overhang 204. Again, the overhang 204 may extend a large distance beyond the die and may extend to a sidewall of a cavity in which the die 110 is mounted, so that substantially all light that is emitted from the cavity passes through the preform. FIG. 2E illustrates the use of a preform of FIG. 2B along with coupling/adhesive layer 210c that extends along the sidewall of the LED die 110, as well as on the top surface thereof. Finally, FIG. 2F generically illustrates the use of a preform 200 including an optical element 220 therein and/or thereon and a coupling/adhesive layer 210a/210b that attaches the preform 200 and a light emitting die to one another, as shown by arrows 230 and couples the preform 200 and the light emitting die 110 to one another. It will be understood by those having skill in the art that embodiments of FIGS. 2A-2F may be combined in various permutations and combinations. Thus, for example, a preform of FIG. 2D may be used with the solid state light emitting die of FIG. 2C and a preform of FIG. 2E may be used with a solid state light emitting die of FIG. 2D.

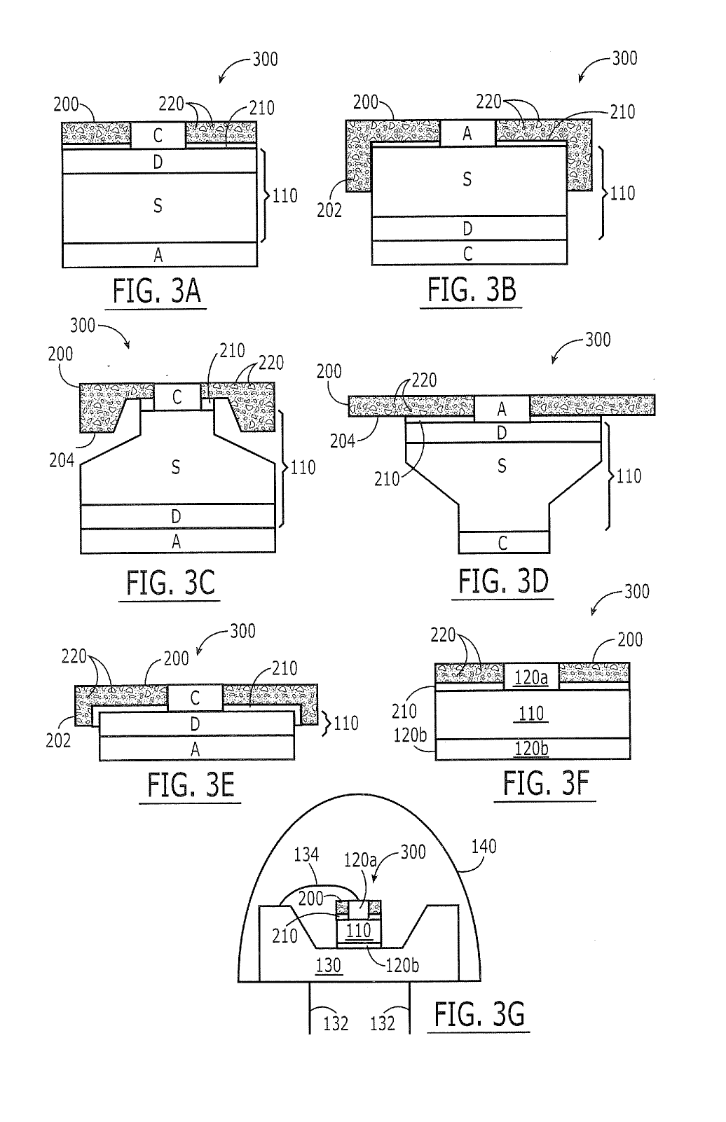

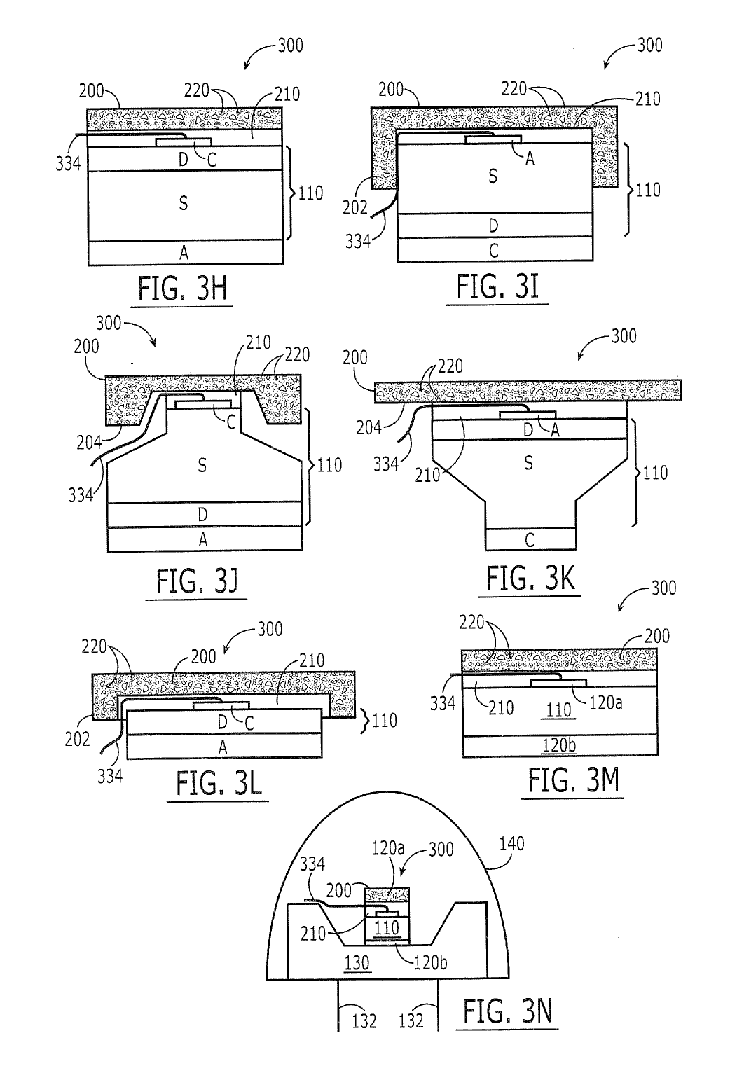

FIGS. 3A-3F correspond to FIGS. 2A-2F, but illustrate the preform 200 attached to the light emitting die 110 by a layer 210 that may comprise a coupling/adhesive layer 210a and/or 210b of FIG. 2A. Accordingly, after attachment of the preform 200 and die 110, a unitary structure 300 of the solid state light emitting die 110 and the preform 200 including an optical element 220, is provided. This unitary structure 300 may then be mounted on a submount 130 and further packaged, as shown in FIG. 3G.

FIGS. 3H-3N correspond to FIGS. 3A-3G, but illustrate the use of a low profile wire bond 334 that does not pass through the preform 200 itself but, rather, passes through the layer 210. In these embodiments, the wire 334 may be bonded to the anode A or cathode C, before placing the adhesive/coupling layer 210 and the preform 200 on the die 110. Low profile wire bonding embodiments of FIGS. 3H-3N may obviate the need for a cutout in the preform 200, which can make alignment of the preform easier during assembly. Moreover, in these embodiments, it may be desirable to provide a thicker layer 210 to accommodate the wire 334 therein. Thicknesses of between about 35 μm and about 70 μm may be used in some embodiments of the present invention.

The use of a preform, according to various embodiments of the invention that were described above, may provide many potential advantages in the fabrication of solid state light emitting devices. For example, as was noted above, it is often desirable to incorporate phosphor and/or other optical elements into the solid state light emitting device. However, when coating a phosphor layer, the coating may be unduly thick and/or undesirably nonuniform. Moreover, a phosphor layer that is incorporated into a dome or shell also may be too thick and/or nonuniform. In sharp contrast, some embodiments of the present invention can provide a relatively thin preform that can provide a relatively high index of refraction and can provide high extraction efficiency. For example, in some embodiments, the preform 200 may include between about 5 and about 70 weight percent silicone-based material or glass, and about 30 to about 95 weight percent phosphor. In some specific embodiments, about 25 weight percent silicone-based material or glass and about 75 weight percent phosphor may be provided. The phosphor particles may be between about 0.5 μm and about 30 μm in size. The phosphor particles may comprise Ce doped Y₃Al₅O₁₂ (Ce:YAG) in some embodiments. In other embodiments, other phosphors, such as Eu2+ doped BOSE, Ce3+ doped nitrides, etc., may be used.

Since the weight percent phosphor can be relatively high, the index of refraction may be increased due to the relatively high index of refraction of phosphor. Stated differently, the index of refraction of the preform may be a weighted average of the index of refraction of the glass and/or silicone-based material and the phosphor particles suspended therein. Extraction efficiency through the relatively high index of refraction preform may thereby be enhanced. Moreover, the preform may be relatively thin, on the order of less than about 100 μm in thickness in some embodiments, and about 30 μm in thickness in other embodiments. Internal absorption or bounce may thereby be reduced because of the relatively thin size of the preform. Finally, since the preform is formed separately from the solid state light emitting die, it can be fabricated and tested without impacting the reliability and/or yield of the solid state light emitting die.

The layer 210 may be a liquid epoxy, as described above. The liquid epoxy may be dispensed onto the preform 200 and/or solid state light emitting die 110 prior to attachment of the preform 200 to the die 110, and then cured after attachment of the preform and the die. For example, the above-described silicone-based liquid epoxy may be dispensed at room temperature and spread using the pick and place force of the preform placement. Curing may then take place by heating in an oven. Adhesive layers of thickness of about 0.1 μm to about 50 μm may be used in some embodiments. Moreover, in other embodiments, a “wicking” adhesive/optical coupling fluid may be applied after placing the preform 200 on the die 110, to provide a thin layer 210.

Preforms may be configured, as was illustrated in FIGS. 2A-2F and 3A-3G, to provide various potential advantages according to some embodiments of the invention. For example, in FIGS. 2B, 2E, 3B and 3E, the preform 200 includes a sidewall 202 that extends at least partially along or adjacent a sidewall of the solid state light emitting die 110. It has been found, according to some embodiments of the present invention that, although light may be primarily emitted from the top surface of the die 110, some low angle sidewall emission may take place. This sidewall emission may adversely impact the desired Correlated Color Temperature (CCT) uniformity of the solid state light emitting device. However, by providing a three-dimensional (nonplanar) preform 200, side emissions may also be “captured” by the phosphor 220 in the preform. Back emissions may also be captured, in some embodiments, by providing the preform on the opposing faces and the sidewalls of the die.

In another example, as illustrated in FIGS. 2C, 2D, 3C and 3D, the preform may include an overhang 204 that is the same thickness as, or is of different thickness than, the remainder of the preform 200. The overhang 204 may capture radiation that is emitted from the sidewall of the solid state light emitting die 110. Moreover, by providing a thicker overhang, the preform can convert, for example, a non-Lambertian radiation pattern to a more desirable Lambertian radiation pattern or can convert a somewhat Lambertian radiation pattern to a more Lambertian radiation pattern, in some embodiments. It will be understood by those having skill in the art that the thicker portions of the preform of FIGS. 2C and 3C may extend toward the solid state light emitting die 110 as shown in FIGS. 2C and 3C, and/or away from the solid state light emitting die.

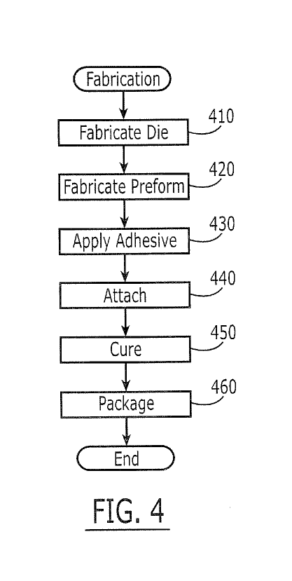

FIG. 4 is a flowchart of operations that may be performed to fabricate solid state light emitting devices according to various embodiments of the present invention. Referring to FIG. 4, at Block 410, the solid state light emitting die, such as the die 110, is fabricated using conventional techniques. At Block 420, a preform, such as the preform 200, is fabricated using techniques that will be described in detail below and/or using other preform fabrication techniques. It will be understood that the dice and preforms may be fabricated out of the order shown in FIG. 4 and/or at least partially overlapping in time.

Then, at Block 430, adhesive, such as coupling/adhesive layer 210, is applied to the die 110 and/or the preform 200. The preform and the die are then attached to one another at Block 440. If needed, the adhesive is cured at Block 450. Subsequent packaging may then take place at Block 460, for example, by bonding the unitary structure of the die 110 and preform 200 to a submount and/or other packaging substrate. It will also be understood that a wire bond may be attached to the die before or after performing the attaching step at Block 440.

FIGS. 2A-2F and 3A-3G illustrated an optical element that comprises phosphor particles 220 that are suspended in the preform 200. However, many other optical elements may be provided in and/or on the preform, according to various embodiments of the present invention. In general, the optical element may be configured to modify at least some of the light that is emitted from the solid state light emitting die 110, by changing its amplitude, frequency and/or direction. These optical elements may include a photoluminescent element (phosphor), as was described above, an optical refracting element such as a lens, an optical filtering element such as a color filter, an optical scattering element such as optical scattering particles, an optical diffusing element such as a textured surface and/or an optical reflecting element such as a reflective surface, that is included in and/or on the preform. Combinations of these and/or other embodiments may be provided. Moreover, two or more preforms may be provided, wherein each preform can perform a different optical processing function, the same optical processing function or overlapping processing functions, depending upon the desired functionality of the solid state light emitting device. Many other examples will now be described in detail.

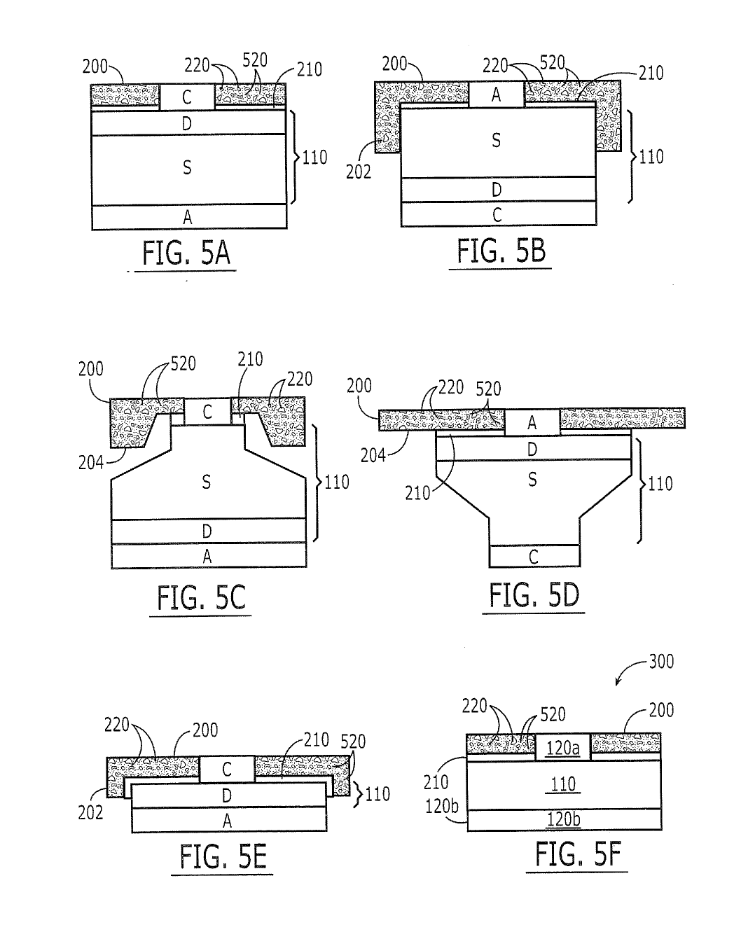

For example, FIGS. 5A-5F correspond to FIGS. 3A-3F, but add optical scattering elements, such as titanium dioxide, aluminum oxide, silicon dioxide and/or other scattering particles 520 to the preform 200 that includes the phosphor particles 220 suspended therein. In some embodiments, between about 0.001 weight percent and about 1 weight percent scattering particles may be added to the preform 200.

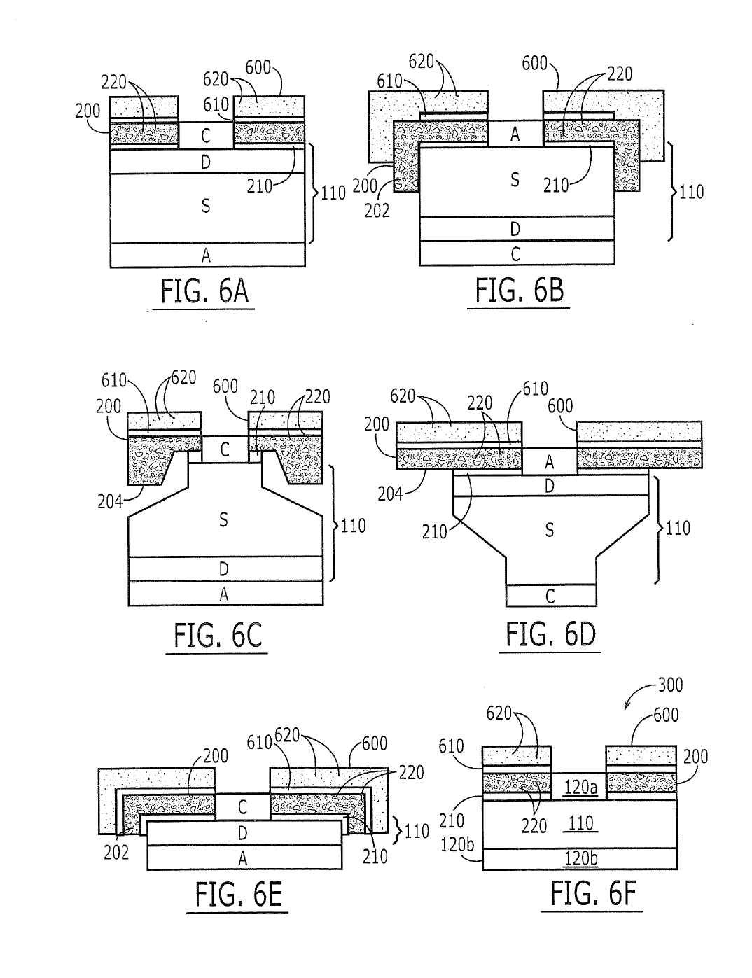

In yet other embodiments, as shown in FIGS. 6A-6F, a second preform 600 that includes scattering particles 620 therein, may be attached/coupled by a second layer 610, to separate the functionalities of light conversion and light scattering into two different preforms 200, 600. The second layer 610 may be the same as, or different from, the first layer 210. It will be understood that the order of the first and second preforms 200 and 600 relative to the solid state light emitting die 110 may be reversed from that shown in FIGS. 6A-6F. Moreover, the first and second preforms need not be congruent to one another or of the same thickness. Finally, from a fabrication standpoint, the first and second preforms 200, 600 may be fabricated and then attached to one another before attaching the assembly of the first and second preforms 200/600 to the solid state light emitting die 110. Alternatively, one of the preforms may be attached to the solid state light emitting die 110 and then the other preform may be attached to the preform that is already attached to the solid state light emitting die 110. Three or more preforms also may be used in other embodiments of the present invention.

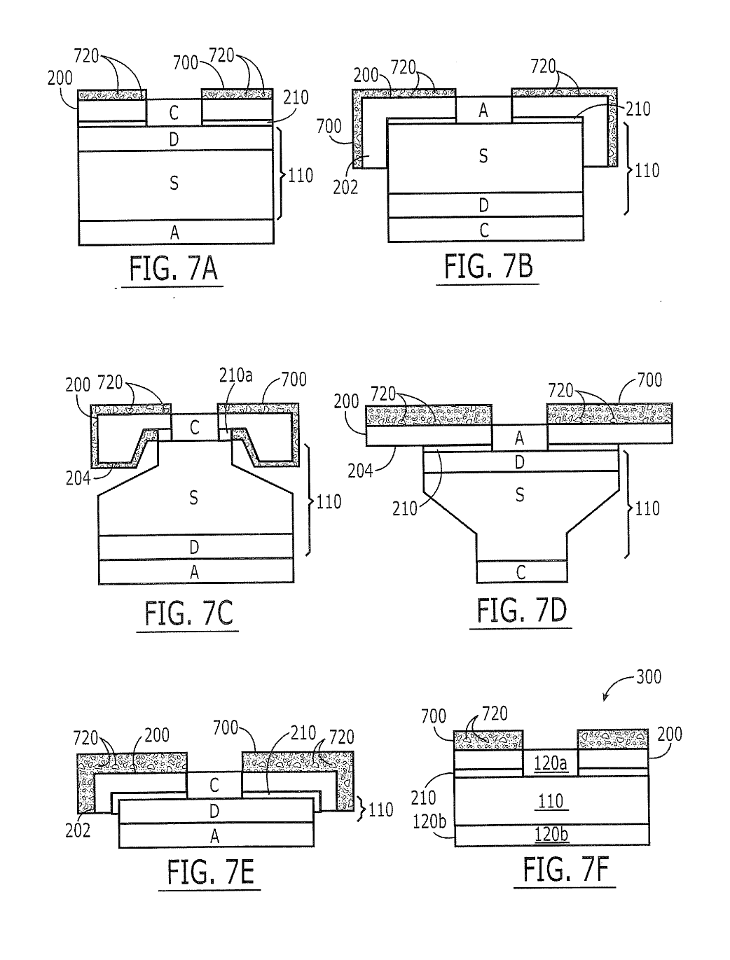

Embodiments of the invention that have been described above have provided an optical element in the preform. Embodiments that are illustrated in FIGS. 7A-7F provide an optical element, such as phosphor particles 720, on the preform 200. In yet other embodiments, the phosphor particles and/or scattering particles 220 may be provided in the preform 200 as was described in connection with FIGS. 2, 3 and 5, and a coating of phosphor particles and/or scattering particles may be provided on the preform as well, as illustrated in FIG. 7. The coating may be provided by coating a preform at any point during its fabrication and then by attaching a coated preform to the solid state light emitting die. However, in other embodiments, coating may be performed after the preform is attached to the die.

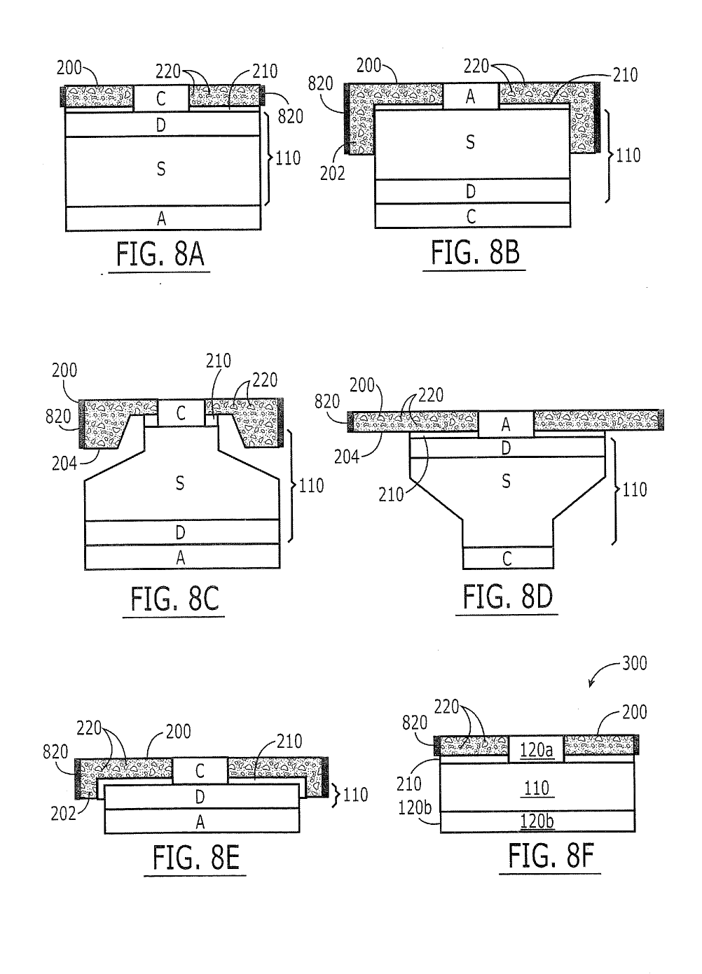

FIGS. 8A-8F illustrate other embodiments of the present invention, wherein a reflector 820 is provided on the preform 200, for example on a sidewall of the preform 200. The reflector 820 may change the radiation pattern of the light emitting die by reflecting stray side radiation back into a main radiation path. The reflector 820 may be created by selectively metallizing the preform 200 before attachment to the solid state light emitting die. In other embodiments, the preform 200 may be metallized after it is attached. It will be understood that mirrors and/or other reflectors 820 may be combined with the use of phosphor 220, scattering particles, multiple preforms and/or any of the other embodiments described herein. It will also be understood that the metallization also may be used to provide electrical traces, wiring and/or contacts, so as to provide an electrical element in and/or on the preform.

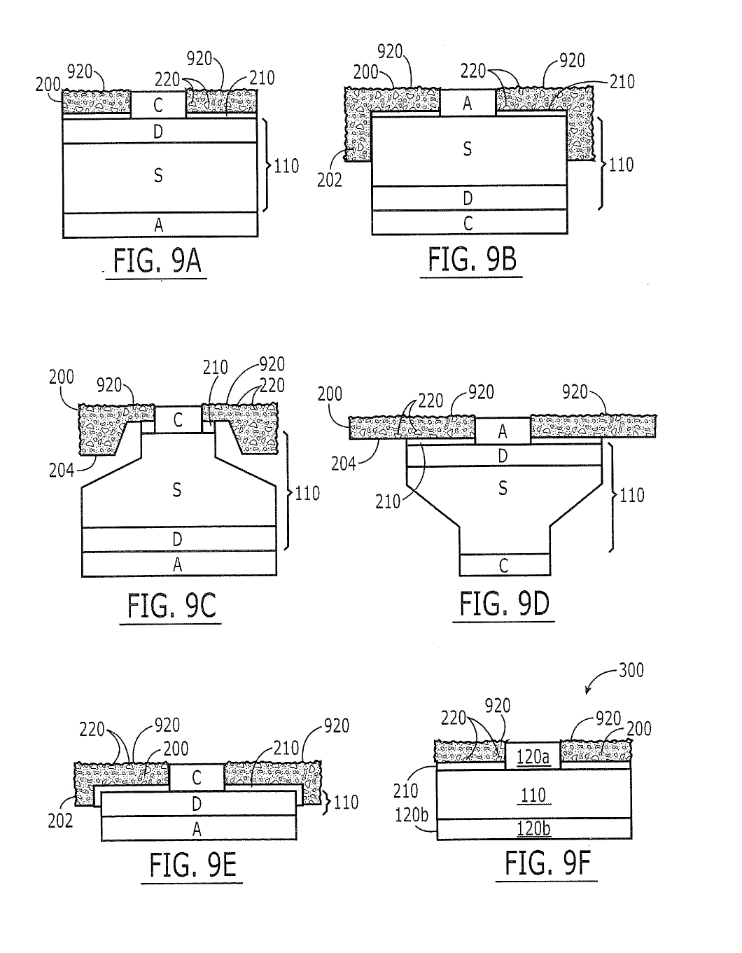

FIGS. 9A-9F illustrate other embodiments of the present invention, wherein the optical element is a diffuser 920 that is formed by texturing a surface of the preform 200. Etching, molding, sandblasting and/or other techniques for texturing are well known to those having skill in the art. For example, surface texturing of a glass substrate is described in a publication by Merz et al., entitled A novel micromachining technology for structuring borosilicate glass substrates, Transducers, 12^{th} International Conference on Solid State Sensors Actuators and Microsystems, IEEE, Vol. 1, June 2003, pp. 258-261. As is also well known, texturing can provide diffusion of emitted radiation that can allow more uniform CCT. It will also be understood that texturing may be provided on a separate preform, and may be combined with any of the other embodiments of the invention that are described herein. Moreover, rather than texturing 820, a die-scale lens and/or an array of microlenses also may be provided on the surface of the preform 200, to provide further optical processing. In other embodiments, these lenses may be embedded in the preform.

It will be understood by those having skill in the art that the surface of a solid state light emitting die itself may be textured by etching the semiconductor material. Unfortunately, this etching may decrease the yield and/or reliability of the solid state light emitting die. In sharp contrast, embodiments of the present invention can texture a separate preform using conventional etching techniques, and then use this textured preform to reduce or obviate the need to texture the solid state light emitting die itself.

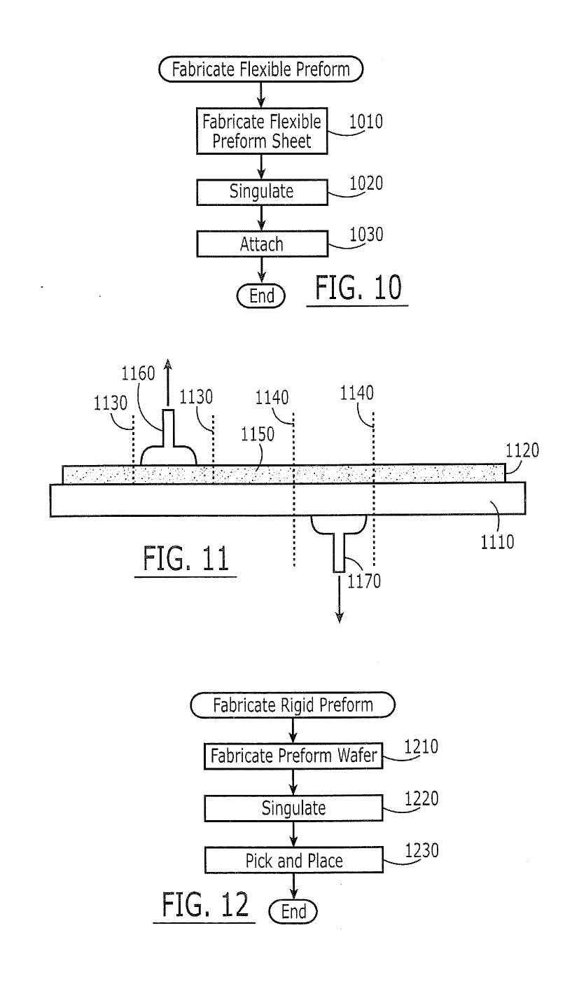

FIG. 10 is a flowchart of operations that may be performed to fabricate a preform, according to various embodiments of the present invention, which may correspond to Block 420 of FIG. 4. These embodiments fabricate a flexible preform. As shown at Block 1010, a flexible preform sheet is fabricated. The flexible preform sheet can be molded to the desired size and shape using conventional molding techniques. For example, as illustrated in FIG. 11, a flexible preform sheet 1120 may be coated on a carrier substrate, such as a glass substrate 1010. Coating may take place, for example, by spin-coating a mixture of silicone-based material, phosphor and/or scatterers onto a carrier substrate. An optional release layer may be provided between the coated layer 1120 and the substrate 1110. The coating 1120 may be cured using heat, light and/or other conventional techniques. Metallization, lenses and/or other devices may be attached to the coating 1120 before and/or after curing.

Referring back to FIG. 10, at Block 1020, the coating 1120 is singulated to form individual preforms 1150. Two embodiments of singulation may be used, according to some embodiments of the present invention. In some embodiments, as shown by dashed lines 1130 in FIG. 11, the coating 1120 is singulated but the substrate 1110 is not singulated. The singulated preform 1150 may then be removed from the substrate 1110 using a pick and place and/or other conventional mechanism 1160, and attached as shown at Block 1030. In other embodiments, the carrier substrate 1110 may also be singulated, in addition to the coating 1120, as shown by dashed lines 1140, to provide a rigid platform for pick and place systems 1170 to attach the preform 1150 to the die 110. In these embodiments, after attaching the preform 1150 to the die, the singulated substrate 1110 may be removed from the singulated preform 1150. In other embodiments, the singulated substrate 1100 may be retained.

Other embodiments of the present invention may provide rigid preforms that may comprise, for example, glass. FIG. 12 illustrates operations that may be performed to fabricate rigid preforms, according to some embodiments of the present invention, which may correspond to Block 420 of FIG. 4.

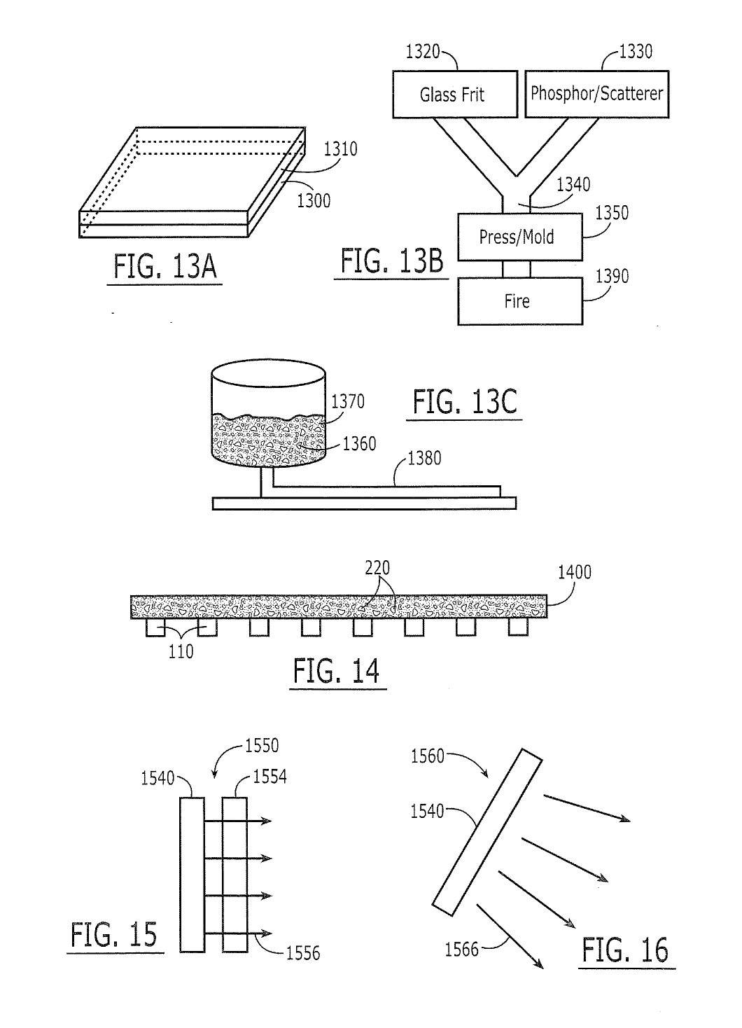

Referring to FIG. 12, at Block 1210, a preform wafer is fabricated. The preform wafer may be fabricated using a wafer blank, using powders and/or using molten materials, as will be described in connection with FIGS. 13A, 13B and 13C, respectively. For example, as shown in FIG. 13A, a glass blank 1300 may be provided that may be, for example, about two inches square by about 30 μm thick, and which is widely available. Other sizes/shapes of glass blanks may be used. The glass blank 1300 is coated with phosphor 1310 using conventional coating techniques. In other embodiments, the glass blank 1300 may be coated with a mixture of phosphor and scattering elements. The coating may be cured. Moreover, in still other embodiments, the glass blank 1300 may be metallized or etched to provide other optical or electrical elements.

In contrast, in embodiments of FIG. 13B, a preform wafer is fabricated using powders. In particular, glass frit, which is a powdered glass, and which is commonly available from Dupont, Cabot and others may be mixed with phosphor, scatterer or other particles 1330 in a mixer 1340. The powders may then be pressed and molded as shown at 1350, and then fired, as illustrated at Block 1390, to create a glass wafer containing phosphor/scatterer/other particles therein. Finally, in other embodiments, as shown in FIG. 13C, the preform wafer may be fabricated in a molten state by mixing phosphor particles 1360 with molten glass 1370, and then laying the mixture on a temporary substrate 1380 to solidify.

Referring back to FIG. 12, at Block 1220, the preform wafer is then singulated using dicing saws, etching, scoring, lasering and/or other conventional techniques. At Block 1230, conventional pick and place equipment may then be used to adhesively attach the preform on the solid state light emitting die. Accordingly, embodiments of FIG. 12 may use glass preforms and conventional pick and place equipment to attach the glass preforms. Glass blanks are widely used in microelectronic fabrication, for example, to form LCD and plasma displays, so that equipment for forming, processing, singulating and otherwise manipulating glass wafers and singulated devices are widely available. High speed automated manufacturing thereby may be provided.

Accordingly, some embodiments of the present invention can use a flexible, semi-flexible (hardness Shore A) or hard (hardness Shore D) silicone material loaded with phosphor particles and/or other materials at a desired concentration, to achieve an appropriate color point. The silicone material with suspended phosphor particles may be potted in a small cavity (for example, using a stencil and screen printing technique) to make a preform after it is cured. This semi-flexible preform may be a delicate material, as it may be on the order of the size of the light emitting die (for example, about 1000 μm×1000 μm) with a thickness of between about 15 μm and about 75 μm, depending on the concentration, particle size, etc. These preforms may be handled by tweezers, but it may be difficult to handle these preforms with conventional automated equipment unless a rigid carrier substrate is provided.

Other embodiments of the present invention use the high temperature stability of Ce:YAG phosphor material and/or other phosphor materials (such as red phosphors used to make warm white light), to mix the appropriate concentration with glass frit (powder) or mix with thick film glass overcoat materials that may currently be used in thick film technology, or to mix phosphor into molten glass (for example using a nutating type mixer) at a desired concentration. A sheet of glass with phosphor particles suspended therein is fabricated to a desired thickness. The sheet is then diced for individual preforms.

The suspension of phosphor particles, such as Ce:YAG phosphor particles in a glass matrix or substrate, according to some embodiments of the invention, may provide many potential advantages. In particular, the quality and/or size of the phosphor particles may be well controlled and may not be degraded by suspending the phosphor particles in glass. Moreover, the melting temperature of the phosphor particles may be relatively high, for example about 1200° C. compared to the relatively low melting temperature of glass frit, such as about 800° C. Accordingly, the fabrication of the preform need not impact the mechanical/optical properties of the phosphor material. The phosphor materials may thereby remain intact, and suspended in the matrix of glass.

The suspending of phosphor particles, such as Ce:YAG phosphor particles, in a glass matrix may be contrasted with the fabrication of YAG glass-ceramic phosphors for white LEDs, as described in publications by Fujita et al., entitled YAG glass-ceramic phosphor for white LED (I): background and development, Proc. of SPIE, Fifth International Conference on Solid State Lighting, Ferguson, Editors, Vol. 5941, 594111 (Sep. 14, 2005), and Tanabe et al., entitled YAG glass-ceramic phosphor for white LED (II): Luminescence characteristics, Proc. of SPIE, Fifth International Conference on Solid State Lighting, Ferguson, Editors, Vol. 5941, 594112 (Sep. 13, 2005). In these publications, a glass-ceramic of Ce-doped SiO₂—Al₂O₃—Y₂O₃ is formed, in contrast to the use of Ce-doped Y₃Al₅O₁₂ particles suspended in an SiO₂ matrix, according to some embodiments of the present invention.

As was described above, in some embodiments, the preforms may be planar preforms that are the same size and shape as a surface of the light emitting die. In other embodiments, the preform may be molded by forming mold cavities in a desired shape, to provide, for example, wire bond notches in a square preform and/or to allow the preform to fit on and around the die surface. The mold cavity is then filled with a glass/phosphor suspension, cured and then removed from the mold. In other embodiments, desired shapes may be formed by etching a preform after it is formed. Moreover, in some embodiments, three-dimensional preforms may be fabricated that can provide preforms having a shallow cup shape to allow edge of the die coverage by the preform, with appropriate cutouts for wire bonds and/or other features. Moreover, the preform may have varying thickness, to match the light intensity of the LED, which can increase or maximize the uniformity of light conversion, and thereby provide more uniform illumination.

Some embodiments of the present invention can allow mass production of preforms of a hard material that can be handled by automated equipment. The material system of the preform including the phosphor suspended therein can be extremely stable at high temperature and, thus, can be put directly on or next to the light emitting surface. An adhesive, such as a small amount of clear silicone encapsulant, may be used to adhere the preform to the die surface and obtain a desired optical coupling. Concerns regarding silicone encapsulant interacting with phosphor may be reduced or eliminated, to reduce or eliminate reversion, browning, bubbling and/or cohesive failing.

It also may be difficult conventionally to coat phosphor at the edges/sidewalls of a die. However, using a three-dimensional preform, the phosphor may be provided at the edges and/or sidewalls, as was described above.

As was also described above, in some embodiments, phosphor and glass material are mixed and placed on a substrate, spin leveled or squeegee leveled, cured, diced on blue tape, and presented to a pick and place machine as a die sheet, for volume manufacturing. Yet other embodiments can provide a textured surface on the preform and/or microlenses in/on the preform. These features can potentially increase light output from the preform, as well as potentially enhance color mixing of converted light (for example yellow) and escaped light (for example blue).

Embodiments of the present invention have been described above in connection with a preform that is adhesively attached to a single LED. However, in other embodiments, as illustrated in FIG. 14, large preform sheets 1400 could be used to adhesively attach multiple LED dice 110 in large fixtures. Different amounts of phosphor 220 in these sheets 1400 may be used to make different temperatures of white light, depending on which sheets are used. Different types of light, such as morning sunlight, noonday sunlight, evening light and/or other colors, may then be provided, by changing or adding/subtracting phosphor sheets for emission control.

Some embodiments of the present invention can provide very thin preforms on the order of about 15 μm to about 75 μm in thickness, having a relatively high concentration of phosphor particles, such as up to 95 weight percent phosphor particles. Silicone encapsulant need only be used as an adhesive layer to adhesively attach the preform and the light emitting die. Moreover, the silicone encapsulant or other adhesive can at least partially compensate for surface roughness of the preform and/or the solid state light emitting die.

Referring to FIG. 15, a lighting panel 1540 including a plurality of light emitting devices according to some embodiments of the invention may be used as a backlight for a display such as a liquid crystal display (LCD) 1550. Systems and methods for controlling solid state backlight panels are described, for example, in U.S. patent application Ser. No. 11/368,976, filed Mar. 6, 2006 entitled Adaptive Adjustment of Light Output of Solid State Lighting Panels, which is assigned to the assignee of the present invention and the disclosure of which is incorporated herein by reference in its entirety. As shown in FIG. 15, an LCD 1550 may include a lighting panel 1540 that is positioned relative to an LCD screen 1554 such that light 1556 emitted by the lighting panel 1540 passes through the LCD screen 1554 to provide backlight for the LCD screen 1554. The LCD screen 554 includes appropriately arranged shutters and associated filters that are configured to selectively pass/block a selected color of light 1556 from the lighting panel 1540 to generate a display image. The lighting panel 1540 may include a plurality of light emitting devices according to any of the embodiments described herein.

Referring to FIG. 16, a lighting panel 1540 including a plurality of light emitting devices according to some embodiments of the invention may be used as a lighting panel for a solid state lighting fixture or luminaire 1560. Light 1566 emitted by the luminaire 1560 may be used to illuminate an area and/or an object. Solid state luminaires are described, for example, in U.S. patent application Ser. No. 11/408,648, filed Apr. 21, 2006, entitled Solid State Luminaires for General Illumination, which is assigned to the assignee of the present invention and the disclosure of which is incorporated herein by reference in its entirety.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A solid state light emitting device comprising:
a solid state light emitting die that is configured to emit light upon energization thereof;
a preform that is configured to allow at least some light that is emitted from the solid state light emitting die to pass therethrough;
a layer that attaches and optically couples the preform and the solid state light emitting die to one another; and
an optical element in and/or on the preform that is configured to modify at least some of the light that is emitted from the solid state light emitting die.

2. A device according to claim 1 wherein the preform comprises glass.

3. A device according to claim 1 wherein the preform comprises a silicone-based material.

4. A device according to claim 1 wherein the preform comprises an inflexible material.

5. A device according to claim 1 wherein the solid state light emitting die includes an external contact pad and wherein the preform is shaped so as to expose the external contact pad.

6. A device according to claim 1 wherein the optical element comprises a photoluminescent element, an optical refracting element, an optical filtering element, an optical scattering element, an optical diffusing element, an optical reflecting element and/or another preform, in and/or on the preform.

7. A device according to claim 1 further comprising an electrical element in and/or on the preform.

8. A device according to claim 1 wherein the preform is of variable thickness.

9. A device according to claim 1 wherein the preform includes a preform side wall that is configured to extend along a side wall of the solid state light emitting die.

10. A device according to claim 1 wherein the optical element is configured to modify at least some of the light that is emitted from the solid state light emitting die by changing amplitude, frequency and/or direction of at least some of the light that is emitted from the solid state light emitting die.

11. A device according to claim 1 wherein the preform is a first preform, the layer is a first layer and the optical element is a first optical element, the solid state light emitting device further comprising:
a second preform that is configured to allow at least some light that is emitted from the solid state light emitting die to pass therethrough;
a second layer that attaches and optically couples the second preform and the first preform to one another remote from the solid state light emitting die; and
a second optical element in and/or on the second preform that is configured to further modify at least some of the light that is emitted from the solid state light emitting die.

12. A device according to claim 1 wherein the preform is of same shape and size as a surface of the solid state light emitting die.

13. A device according to claim 1 wherein the preform extends beyond a surface of the solid state light emitting die.

14. A device according to claim 1 wherein the preform comprises a suspension of phosphor particles in glass.

15. A device according to claim 14 wherein the preform comprises between about 30 and about 95 weight percent phosphor.

16. A device according to claim 15 wherein the preform further comprises about 0.001 to about 1 weight percent optical scattering particles.

17. A device according to claim 15 wherein the preform comprises a textured surface.

18. A device according to claim 15 wherein the solid state light emitting die includes an external contact pad and wherein the preform is shaped so as to expose the external contact pad.

19. A device according to claim 1 wherein the layer comprises an adhesive layer that adhesively attaches and optically couples the preform and the solid state light emitting die to one another.

20. A device according to claim 1 further comprising a submount that is connected to the solid state light emitting die that includes the preform thereon.

21. A device according to claim 1 wherein the solid state light emitting die is a semiconductor light emitting diode die.

22. A solid state light emitting device comprising:
a solid state light emitting die that is configured to emit light upon energization thereof, and
a glass preform including phosphor particles suspended therein, on the solid state light emitting die.

23. A device according to claim 22 wherein the solid state light emitting die includes an external contact pad and wherein the glass preform including phosphor particles suspended therein is shaped so as to expose the external contact pad.

24. A device according to claim 22 further comprising an electrical element in and/or on the glass preform including phosphor suspended therein.

25. A device according to claim 22 wherein the glass preform including phosphor particles suspended therein extends beyond a surface of the solid state light emitting die.

26. A device according to claim 22 wherein the glass preform including phosphor particles suspended therein comprises between about 30 and about 95 weight percent phosphor.

27. A device according to claim 26 wherein the glass preform including phosphor particles suspended therein further comprises about 0.001 to about 1 weight percent optical scattering particles.

28. A device according to claim 22 wherein the glass preform including phosphor particles suspended therein comprises a textured surface.

29. A device according to claim 22 wherein the phosphor particles comprise Ce:YAG phosphor.

30. An optical processing device for a solid state light emitting die comprising:
a glass preform that is sized and shaped to attach to the solid state light emitting die, the glass preform including phosphor particles suspended therein.

31. A device according to claim 30 wherein the solid state light emitting die includes an external contact pad and wherein the glass preform including phosphor particles suspended therein is shaped so as to expose the external contact pad.

32. A device according to claim 30 further comprising an electrical element in and/or on the glass preform including phosphor suspended therein.

33. A device according to claim 30 wherein the glass preform including phosphor particles suspended therein comprises between about 30 and about 95 weight percent phosphor.

34. A device according to claim 33 wherein the glass preform including phosphor particles suspended therein further comprises about 0.001 to about 1 weight percent optical scattering particles.

35. A device according to claim 30 wherein the glass preform including phosphor particles suspended therein comprises a textured surface.

36. A device according to claim 30 wherein the phosphor particles comprise Ce:YAG phosphor.

37. An optical processing precursor for solid state light emitting dice comprising:
a substrate;
a plurality of preforms on the substrate that are sized and shaped to attach to the solid state light emitting dice, a respective preform being configured to allow at least some light that is emitted from a respective solid state light emitting die to pass therethrough; and
an optical element in and/or on a respective preform that is configured to modify at least some of the light that is emitted from the respective solid state light emitting die.

38. A precursor according to claim 37 wherein the preforms comprise singulated preforms.

39. A precursor according to claim 38 wherein the singulated preforms comprise flexible material and wherein the substrate comprises a singulated substrate.

40. A precursor according to claim 38 wherein the singulated preforms comprise glass and wherein the optical element comprises phosphor particles suspended in the singulated glass preforms.

41. A method of fabricating a solid state light emitting device comprising:
attaching a preform and a solid state light emitting die to one another, wherein the preform is configured to allow at least some light that is emitted from the solid state light emitting die to pass therethrough and the preform includes an optical element therein and/or thereon that is configured to modify at least some of the light that is emitted from the solid state light emitting die.

42. A method according to claim 41 wherein attaching comprises picking the preform from a substrate and placing the preform that was picked onto the solid state light emitting die.

43. A method according to claim 42 wherein placing is preceded by coating adhesive on the preform and/or the solid state light emitting device.

44. A method according to claim 42 wherein picking is preceded by singulating the preform.

45. A method of fabricating a preform for a solid state light emitting device comprising:
suspending phosphor particles in glass.

46. A method according to claim 45 wherein suspending comprises:
mixing glass frit and phosphor particles; and
heating to melt the glass frit and form a glass preform including the phosphor particles suspended therein.

47. A method according to claim 45 wherein suspending comprises:
mixing phosphor particles into molten glass; and
allowing the molten glass to cool.
